(19) United States
(12) Patent Application Publication
(10) Pub. No.: US 2002/0043978 A1
(43) Pub. Date: Apr. 18, 2002

(54) Outlet heat indicator

(76) Inventor: Kevin B McDonald, Portland, OR (US)

Correspondence Address: W. KARL RENNER, Fish & Richardson P.C., 601 Thirteenth Street, NW, Washington, DC, 20005, US

(21) Appl. No.: 09/978,629

(22) Filed: Oct. 18, 2001

Related U.S. Application Data
(60) Provisional application No. 60/241,002, filed on Oct. 18, 2000.

(51) Int. Cl. G01R 31/00

(52) U.S. Cl. 324/508

(57) ABSTRACT

A visual indicator notifies an occupant of an unsafe wiring condition in an electrical outlet or switch. The visual indicator and the electrical conductors inside the outlet being thermally connected, but electrically separated. When a threshold temperature is reached which is outside the normal operating temperature of an electrical outlet, the visual indicator will change state to notify occupants of a wiring problem.

### CROSS REFERENCE TO RELATED APPLICATIONS

This application claims priority from U.S. Provisional Application No. 60/241,002, filed Oct. 18, 2000, and titled “Outlet Heat Indicator,” which is incorporated by reference.

### FIELD OF THE INVENTION

This invention is related to detecting and visually indicating heat within electrical outlets, and, more particularly, to providing a visual indication of unsafe conditions within electrical outlets that may be gleaned through the generation of heat at those outlets.

### BACKGROUND

Temperature fluctuations are problematic in various contexts. From shipping packages to heavy equipment, it is often important to maintain desired temperature ranges and to be informed when temperatures outside those ranges are experienced. To this end, temperature sensitive labels and temperature sensing equipment have been developed. In the context of shipping, temperature labels have been affixed to packages to ensure that temperatures outside of a desired range have not been encountered. Similarly, temperature sensing equipment has been used in the context of monitoring machinery and equipment to determine whether the machinery or equipment is operating outside of an optimal temperature range.

Temperature fluctuations also may be problematic in electrical connections. Unlike the packaging and equipment contexts described above, temperature fluctuations in electrical connections are sometimes indicative of other problems. Among these problems, the CPSC Guide To Home Wiring Hazards, U.S. Government Printing Office, 1996-718-282/82650, identifies short circuits, loose wires and corroded or loose connections. Such fluctuations in temperature are particularly problematic in the context of household electrical connections, where lives may be lost when fires result from faulty electrical connections.

Yet, these problems frequently go undetected until tragedy occurs. For instance, from 1993-1997, our government reported that an average of approximately 4700 fires were started annually at switches, receptacles and outlets causing 29 deaths, 144 injuries and $60.8MM in property damage. And, these numbers are expected to grow as the wiring infrastructure of homes grows older and the electrical loads applied to that wiring infrastructure increase with new classes of appliances such as larger computers and home entertainment systems.

### SUMMARY

In one general aspect, a visual indicator that is physically connected to an electrical connector or outlet senses the internal temperature of the electrical connector or outlet through a thermally conductive path, and provides a visual indication based on the temperature of the electrical connector, e.g., changing color or appearance when the electrical connector or outlet operates at an abnormal or unsafe temperature. Although the visual indicator is thermally coupled to the electrical connector, at least the exposed portions of the indicator may be electrically insulated.

The details of one or more implementations are set forth in the accompanying drawings and the description below. Other features, objects, and advantages of the invention will be apparent from the description and drawings, and from the claims.

### BRIEF DESCRIPTION OF THE DRAWINGS

FIGS. 1A and 1B illustrate examples of an outlet cover integrating an outlet heat indicator.

FIGS. 2A and 2B illustrate examples of outlet receptacles integrating an outlet heat indicator.

FIGS. 3A and 3B illustrate an example of a plug extender integrating an outlet heat indicator.

FIG. 4 illustrates an example of a retrofittable outlet heat indicator.

### DETAILED DESCRIPTION OF DRAWINGS

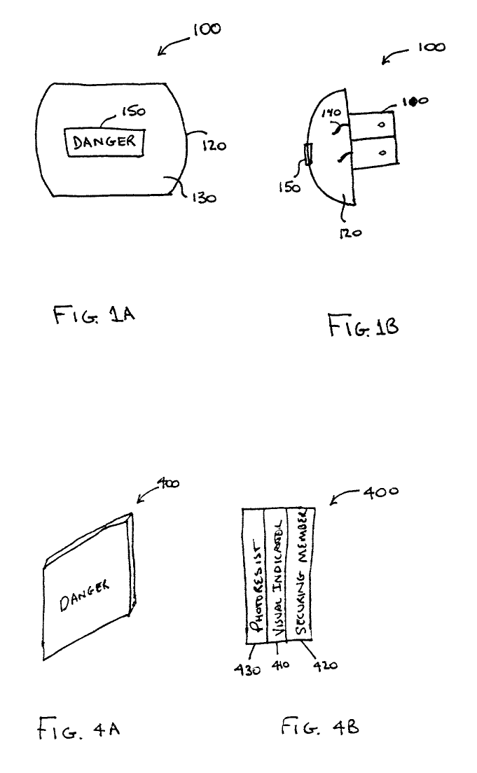

A visual indicator notifies an occupant of an unsafe wiring condition at an electrical outlet or switch. The temperature of internal components of the outlet or switch are transmitted by the thermally conductive path to a temperature sensor/visual indicator. When a threshold temperature is reached, the visual indicator will change state to reflect the threshold condition, e.g., identifying a dangerous condition when the threshold condition is indicative of high heat. The visual indicator may maintain its changed state to reflect a dangerous condition if, at any time, a dangerous operating condition has been detected. Various configurations for the visual indicator are contemplated, e.g., a safety cover that plugs into the outlet with the visual indicator on the outside of the cover, an electrical outlet or switch cover having an integrated visual indicator, a sleeve or plug extender that is positioned between the outlet and an electrical equipment, and a retrofittable indicator that may be applied to plugs, switches and/or outlet covers. FIGS. 1A-4 illustrate these configurations and are described in greater detail below.

The visual indicator may be physically configured in numerous ways. For instance, the visual indicator may be incorporated into a cover for an inactive or unused electrical outlet. By contrast, the visual indicator may be incorporated into an outlet or switch as a replaceable or an irreplaceable element, or it may be integrated into a sleeve or plug extender that allows an outlet to be used while concurrently checking for unsafe operating temperatures. In any of these and other configurations, the visual indicator may be built-in or retrofitted.

The sensing and indicating material may be a single material or a combination of several different materials. For instance, the indicating material may be a thermal paint or label that changes color when a threshold temperature is reached. Thermal paints and labels generally describe a chemical patch that undergoes a reaction and changes color when a target temperature is reached. Thermal labels also may include substrates or surfaces covered by thermally-sensitive materials, such as wax, having a precise and appropriate melting temperature such that the thermally-sensitive materials are absorbed by the surface or otherwise expose the surface when a threshold temperature is reached or exceeded. Alternatively, the indicating material may be a semiconductor junction whose voltage potential is proportional to temperature, or light emitting devices such as liquid crystal displays (LCDs), light emitting diodes (LEDs), or fluorescent tubes. An LCD may be both a sensing and an indicating device. For instance, it may be possible to employ a special LCD technology otherwise useful in flat plastic thermometers that are incorporated into rulers and bathtub and swimming pool monitors.

The visual indicator typically is non-obtrusive such that it remains concealed until an unsafe condition occurs. For instance, if the indicating material is paint, the color of the paint under normal conditions may blend with the faceplate of the electrical outlet or the color of the object to which it is applied, the color changing to alert an observer only when/after unsafe conditions are detected. Similarly, if the indicating material is less discrete, a heat sensitive material (e.g., wax) that melts away or becomes transparent may be used to hide the indicating material until unsafe conditions are detected. By contrast, the visual indicator may display an affirmative indication of a safe or ordinary operating condition until/unless an unsafe condition is experienced.

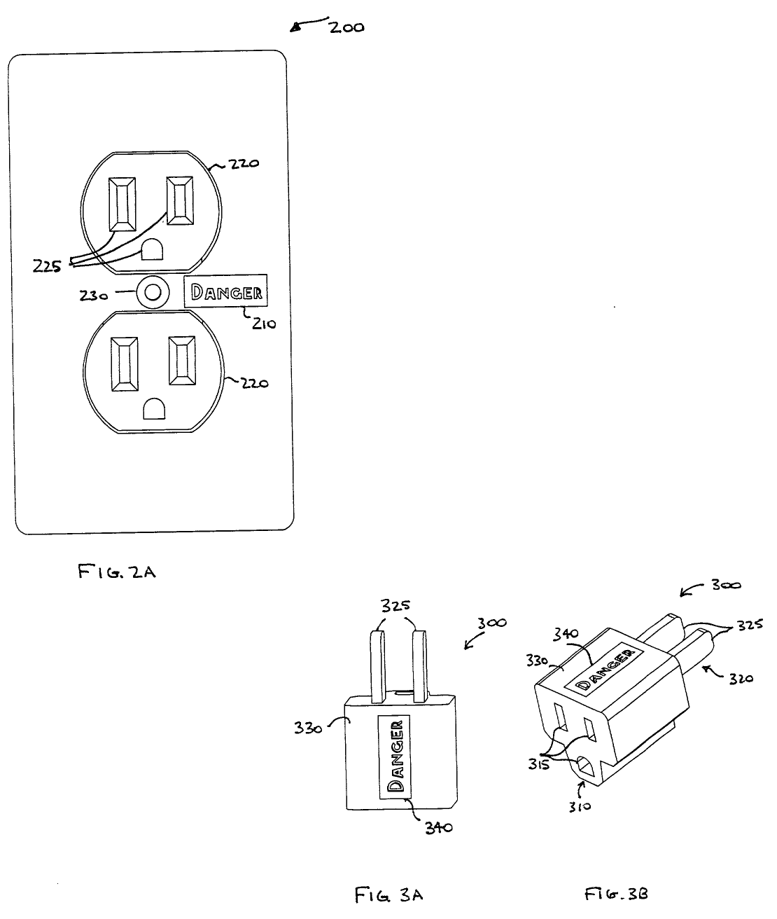

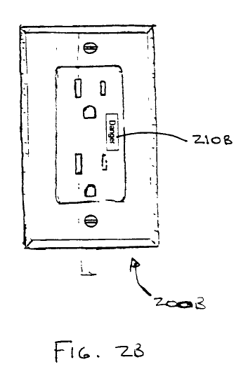

Four exemplary implementations of the outlet indicator are described: (1) an outlet cover (FIGS. 1A and 1B), (2) an outlet or switch cover with an integrated visual indicator (FIGS. 2A and 2B), (3) a plug extender with an integrated visual indicator (FIGS. 3A and 3B), and (4) a temperature sensitive material that is applied and fixed relative to an existing outlet by a securing member (FIG. 4).

Referring to FIGS. 1A and 1B, a plug 100 having an appearance that resembles a traditional child safety outlet cover may integrate a visual indicator. The plug 100 is physically connected to an electrical outlet by prongs 110 that insert into the outlet receptacle such that the cover 120 itself remains visible. Yet, this plug 100 differs in construction and function from traditional child safety outlet covers. The prongs 110 of the plug 100 may be made of a thermal conductor, e.g., metal, to conduct the temperature of the outlet wiring toward the visible surface 130 Of the plug 100. Yet, the prongs 110 remain electrically insulated from the surface 130 of the plug 100. For instance, a rugged paint may be applied to insulate the surface 130 from the prongs 110 electrically. Paints capable of achieving sufficient electrical insulation generally have a U.L. electrical insulation rating comparable to paints used to coat transformer magnet wires and solder masks used to create printed circuit boards. To enhance heat conduction to the surface 130 of the plug 100, and hence improve performance, the prongs 110 may be bent 140 as they extend into the cover 120 at an angle to expose more of the prong 110 surface to the material (e.g., plastic) used to form the cover 120 of the plug 100 (e.g., 90 degrees from the insertion angle). On or viewable from the plug surface 130 is a temperature sensitive label 150 that may have any of various shapes, but is described herein as having a rectangular shape. If the label 150 experiences a temperature indicative of unsafe operating conditions (e.g., 140 degrees F. or greater) for more than a threshold period of time (e.g., 5 seconds), an indication will appear in the plug surface 130 to reflect unsafe operating conditions. For instance, if the label 150 ordinarily has a silver or white color, a different color may be displayed or a colored message may become visible, e.g., stating “warning” or, more specifically, “danger, over-heated wiring, >140 degrees F.”. Various colors may be used for the warning, but red is preferred.

Referring to FIGS. 2A and 2B, the visual indicator may be integrated into an outlet and outlet cover or switch and switch cover. Specifically, FIG. 2A shows one example of a standard wall outlet cover 200 having an integrated visual indicator 210. The visual indicator 210 may be positioned corresponding to the center of the electrical outlets 220 or it 210 may be positioned on either side of the outlets 220, as shown in FIG. 1, to enhance viewability. In either position, the indicator is able to take advantage of the thermally conductive path(s) formed by the screw terminal(s) 230 which may be made of a material compatible with the material used to form the terminal receptacles 225, e.g., metal. However, the screw terminal(s) 230 may be electrically isolated from the outlet 220 by an insulator, e.g., a rugged insulating paint, such that the thermally conductive paths terminate inside the insulating cover 240 of the outlet under the visual indicator 210. In this manner, the thermally conductive paths are able to conduct heat without increasing exposure to electrical current. A temperature sensitive material may be used as the visual indicator 210 to detect and display unsafe heat that is conducted through the thermal paths, as illustrated with respect to the paint described above in the first implementation. FIG. 2B shows a second example of a standard wall outlet cover 200B having an integrated visual indicator 210B.

Referring to FIGS. 3A and 3B, the visual indicator may be integrated into a plug extender. Specifically, FIGS. 3A and 3B show a plug extender 300 that is positioned between a wall outlet and an electrical appliance. One end 310 of the plug extender 300 is a female receptacle 315 where the plug from an electrical appliance is inserted. The other end 320 is a male plug 325 for inserting the plug extender into a wall outlet. Inside the plug extender 300, the metal parts that make up the electrical connections are positioned proximate to the surface of the insulating material forming the plug extender body 330. Integrated into or viewable from the surface of the plug extender body 330, a visual indicator 340 (e.g., thermal paint) is positioned. If an unsafe operating temperature is reached inside the outlet, at the plug or at a nearby cord of the electrical appliance, the unsafe operating temperature is conducted to the visual indicator 340, which changes state to present or expose an appropriate warning message, as described above.

Referring to FIGS. 4A and 4B, the visual indicator may be implemented using a film or layer 400 of temperature sensitive material that is capable of being applied and secured relative to existing outlets or switch covers, plug heads, cords, surge protectors, and/or other devices to detect and indicate unsafe operating temperatures in or around electrical outlets. The layer 400 of temperature sensitive material generally has the shape of a thin film or sheet 410 that is secured to the retrofit device using a securing member 420, such as an adhesive or a fastener, which is capable of securing a position of the visual indicator relative to an electrical outlet such that a thermally conductive path conducts heat within the electrical outlet to the visual indicator through the device to which the visual indicator is affixed.

In areas exposed to direct light, it may be necessary to cover the temperature sensitive material with a photoresistive material to prevent heating otherwise caused by the light exposure. The photoresistive material may take any of various forms, including a thin transparent film (see layer 430 in FIG. 4B) or an opaque material that is separated from the temperature sensitive material to provide shade (not shown). Similarly, photoresistive materials may be applied to the visual indicators described with respect to FIGS. 1A-3B.

In any event, a threshold accuracy tolerance of approximately +/−2 degrees C. is sufficient to detect unsafe operating conditions in electrical outlets. Temperature sensing equipment may be used to achieve this tolerance in each of chemical, mechanical, electrical and other arts. For instance, in the chemical arts, temperature sensing equipment may include thermal crayons and/or thermal labels. Similarly, in the mechanical arts, temperature sensing equipment may include bimetallic switches, waxes with precise melting temperatures, and temperature sensitive LCD materials. Electrical methods available for achieving these tolerances are likewise available, including sensors whose resistance, output current, or voltage potential are related to temperature such that their output is amplified and/or conditioned to reflect temperature fluctuations. The amplification and conditioning may be achieved through microelectronics circuitry, or otherwise.

The implementations described herein are not intended to preclude other implementations that may realize from the concepts described. Rather, one of ordinary skill would readily appreciate various other implementations and advantages that may be realized from the underlying concepts. For instance, rather than through visual means, the indicator may involve a different sense or a combination of senses, such as smell or sound. The smell or sound is generally perceivable in that persons within a general vicinity of the outlet are alerted to the undesirable temperature when produced. In one such implementation, the outlet cover may include a wax that produces a distinct odor when an undesirable amount of heat is detected at the electrical outlet. Such a wax may be easily combined with the visual indication described previously. Similarly, an audible warning is easily implemented and combined with other warnings.

I claim:

1. An indicator that visually reflects the existence of an undesirable amount of heat within an electrical outlet, comprising:
a heat detector structured and arranged to detect and visually indicate the existence of an amount of heat exceeding a threshold level, the threshold level being related to an undesirable amount of heat at the electrical outlet and the heat detector being electrically insulated from the electrical outlet; and
a securing member capable of securing a position of the heat detector relative to an electrical outlet such that a thermally conductive path exists between the heat detector and electrical conductors inside the electrical outlet, wherein the thermally conductive path conducts heat within the electrical outlet to the heat detector to enable an indication when an undesirable amount of heat is detected at the electrical outlet.

2. The apparatus of claim 1, wherein the heat detector includes a heat sensitive material that changes state when heat exceeding the threshold level is detected.

3. The apparatus of claim 2, wherein the heat detector latches into the changed state when an amount of heat exceeding the threshold level has been detected.

4. The apparatus of claim 2, wherein the heat sensitive material is a thermal label.

5. The apparatus of claim 2, wherein the heat detector includes a warning indicator and a cover that ordinarily prevents visual perception of the warning indicator, the cover exposing the warning indicator when the amount of heat detected by the heat detector exceeds the threshold level.

6. The apparatus of claim 5, wherein the cover includes a wax that melts to expose the warning indicator when the threshold level is reached at the detector.

7. The apparatus of claim 1, wherein the heat detector includes microelectronics and an active display driven by the microelectronics to generate a visual indication when the amount of heat detected by the heat detector exceeds the threshold level.

8. The apparatus of claim 1 where the heat detector includes a liquid crystal device.

9. The apparatus of claim 1, further comprising:
a photoresistive material arranged to prevent heating of the heat detector that may otherwise be experienced due to exposure to light, the photoresistive material being positioned over at least a portion of the heat detector that is exposed to light when secured by the securing member.

10. The apparatus of claim 1, wherein the securing member is an adhesive.

11. The apparatus of claim 1, wherein the securing member is a fastener.

12. The apparatus of claim 1, wherein the securing member is structured and arranged to secure the heat detector to a faceplate of an electrical outlet or switch cover.

13. The apparatus of claim 1, wherein the securing member is structured and arranged to secure the heat detector to a head of an electrical plug designed to engage the electrical outlet.

14. The apparatus of claim 13, wherein the electrical plug is positioned at an end of an electrical cord used to deliver current from the electrical outlet to electrical equipment.

15. The apparatus of claim 14, wherein the electrical cord is included in a surge protector.

16. The apparatus of claim 1, wherein the securing member includes a faceplate of the electrical outlet.

17. The apparatus of claim 1, wherein the securing member includes a head of an electrical plug designed to engage the electrical outlet.

18. The apparatus of claim 17, wherein the electrical plug is positioned at an end of an electrical cord used to deliver current from the electrical outlet to electrical equipment.

19. The apparatus of claim 18, wherein the electrical cord is included in a surge protector.

20. The apparatus of claim 1, wherein the heat detector includes an indicator that produces a perceivable odor to alert persons when an undesirable amount of heat is detected at the electrical outlet.

21. An indicator that visually reflects the existence of an undesirable amount of heat within an electrical outlet, comprising:
a heat detecting means for detecting and visually indicating the existence of an amount of heat exceeding a threshold level, the threshold level being related to an undesirable amount of heat at the electrical outlet and the heat detecting means being electrically insulated from the electrical outlet; and
a securing means for securing a position of the heat detecting means relative to an electrical outlet such that a thermally conductive path exists between the heat detecting means and electrical conductors inside the electrical outlet, wherein the thermally conductive path conducts heat within the electrical outlet to the heat detecting means to enable an indication when an undesirable amount of heat is detected at the electrical outlet.

22. The apparatus of claim 1, wherein the heat detecting means include a heat sensitive material that changes state when heat exceeding the threshold level is detected.

23. The apparatus of claim 2, wherein the heat detecting means latch into the changed state when an amount of heat exceeding the threshold level has been detected.

24. The apparatus of claim 2, wherein the heat sensitive material is a thermal label.

25. The apparatus of claim 2, wherein the heat detecting means include a warning indicator and a cover that ordinarily prevents visual perception of the warning indicator, the cover exposing the warning indicator when the amount of heat detected by the heat detecting means exceed the threshold level.

26. The apparatus of claim 5, wherein the cover includes a wax that melts to expose the warning indicator when the threshold level is reached at the detector.

27. The apparatus of claim 1, wherein the heat detecting means include microelectronics and an active display driven by the microelectronics to generate a visual indication when the amount of heat detected by the heat detecting means exceed the threshold level.

28. The apparatus of claim 1 where the heat detecting means include a liquid crystal device.

29. The apparatus of claim 1, further comprising:
photoresistive means for preventing heating of the heat detecting means that may otherwise be experienced due to exposure to light, the photoresistive material being positioned over at least a portion of the heat detecting means that is exposed to light when secured by the securing means.

30. The apparatus of claim 1, wherein the securing means include an adhesive.

31. The apparatus of claim 1, wherein the securing means include a fastener.

32. The apparatus of claim 1, wherein the securing means secure the heat detecting means to a faceplate of an electrical outlet or switch cover.

33. The apparatus of claim 1, wherein the securing means is structured and arranged to secure the heat detecting means to a head of an electrical plug designed to engage the electrical outlet.

34. The apparatus of claim 13, wherein the electrical plug is positioned at an end of an electrical cord used to deliver current from the electrical outlet to electrical equipment.

35. The apparatus of claim 14, wherein the electrical cord is included in a surge protector.

36. The apparatus of claim 1, wherein the securing means include a faceplate of the electrical outlet.

37. The apparatus of claim 1, wherein the securing means include a head of an electrical plug designed to engage the electrical outlet.

38. The apparatus of claim 17, wherein the electrical plug is positioned at an end of an electrical cord used to deliver current from the electrical outlet to electrical equipment.

39. The apparatus of claim 18, wherein the electrical cord is included in a surge protector.

40. The apparatus of claim 1, wherein the heat detecting means include an indicator that produces a perceivable odor to alert persons when an undesirable amount of heat is detected at the electrical outlet.
